(19) United States
(12) Patent Application Publication
(10) Pub. No.: US 2012/0182651 A1
(43) Pub. Date: Jul. 19, 2012

(54) Shared Electrostatic Discharge Protection For Integrated Circuits, Integrated Circuit Assemblies And Methods For Protecting Input/Output Circuits

(75) Inventors: Thomas Dungan, Fort Collins, CO (US); Phillip Nikkel, Loveland, CO (US)

(73) Assignee: Avago Technologies Enterprise IP (Singapore) Pte. Ltd., Singapore (SG)

(21) Appl. No.: 13/009,664

(22) Filed: Jan. 19, 2011

(51) Int. Cl. H02H 9/00; H01L 23/52

(52) U.S. Cl. 361/56; 257/773; 257/E23.141

(57) ABSTRACT

A method for protecting input/output (I/O) circuits on an integrated circuit (IC) from electrostatic discharge (ESD) is disclosed. The method includes the steps of providing at least one protective device on a surface of a first semiconductor die and applying a conductive shorting layer over a select region of the surface to electrically couple at least one metallic stud to the at least one protective device. After bonding the IC die to a second IC die and/or testing one or more core circuits, the conductive shorting layer is removed to enable high-speed I/O connections arranged in the select region of the semiconductor die. An IC assembly includes first and second semiconductor dice. One of the dice includes a protective device along a surface. An electrically conductive shorting layer couples the protective device to a conductive element that is further coupled to I/O circuit elements.

### BACKGROUND

Conventional electronic systems for computation, communication, and other applications are typically built up from integrated circuits (ICs) arranged in packages or chips and connected to power supplies, circuit elements and other ICs in separate packages or ICs by way of wiring traces on printed circuit boards. Each IC requires connections through the package for power and electrical ground returns, as well as other package connections, which can include both low-rate control signals and high-rate data signals.

Relatively faster ICs include smaller traces and circuit elements. As IC traces and elements become smaller, electrostatic discharge protection increases in importance. An electrostatic discharge is a rapid transfer of electrostatic charge between two objects at different electrostatic potentials. Direct contact, or even bringing the objects in close proximity to each other, can induce such a charge transfer. When the receiving object is an IC or an IC assembly, internal traces and circuit elements can be damaged rendering the IC inoperable or significantly decreasing the useful life of a device made with the damaged IC or ICs.

Electrical connections for the transfer of signals to and from the IC or IC assembly have been protected from ESD by on-chip circuits connected to the chip's terminals (input/output pads) for this purpose. These circuits prevent damage due to ESD events while handling, packaging, shipping, testing, and final assembly. Such protective circuits typically use diodes or silicon-controlled rectifiers coupled to each signal connection to protect the I/O circuits on the IC. Such circuits have proved effective at controlling ESD damage, but they require a significant amount of area and add capacitance to input/output terminals, decreasing performance and increasing power consumption.

The rate of increases in on-circuit density and operating frequency of high-performance ICs have exceeded the rate of increase in interconnections available between packages and printed circuit boards. One method to provide increased communication bandwidth between integrated circuits involves directly bonding one circuit to another, rather than placing each IC in separate packages subsequently connected through traces of a printed circuit board. Such a chip-to-chip bonding approach could effect both the structural and electrical connection between chips by bonding copper terminals of various interconnect lines on the printed circuits together, for example by direct copper fusion bonding, or through patterned solder connections.

Direct chip-to-chip bonding enables area arrays of chip-to-chip interconnections. The area required for definition of a copper stud contact point for direct chip-to-chip attachment is potentially very small, for example down to a few square microns, or eventually even less than one square micron. Such small connections tend to have correspondingly lower parasitic capacitance compared to conventional chip-to-chip interconnections through packages and printed circuit board traces. Because both the required area and the parasitic capacitance are significantly reduced with direct chip-to-chip connections, the overhead penalties in chip area and performance for the addition of ESD protection devices at each terminal are proportionally larger than for conventional interconnections. An objective in direct chip-to-chip bonding is to make high-speed chip-to-chip connections approach within-chip connections in terms of density and performance. To achieve this objective, a method is needed to provide ESD protection for such high-speed bonded chip-to-chip connections without the corresponding area and performance overhead of conventional ESD protection techniques.

### SUMMARY

An embodiment of a method for protecting I/O circuits on an IC from ESD includes the steps of providing at least one protective device on a surface of a first semiconductor die and applying a conductive shorting layer over a select region of the surface to electrically couple at least one conductive stud to the at least one protective device.

An embodiment of an IC assembly includes first and second semiconductor dice. A first semiconductor die has a first surface and opposed surface. The first surface includes at least one protective device within a conductive shorting layer in a select region above the first surface. The conductive shorting layer electrically couples at least one conductive element (e.g., a metallic stud) to the at least one protective device. The second semiconductor die has at least one respective conductive element that when arranged in registration to and coupled with the first semiconductor die completes a circuit between the first semiconductor die and the second semiconductor die.

The figures and detailed description that follow are not exhaustive. The disclosed embodiments are illustrated and described to enable one of ordinary skill to use conductive shorting layer patterning to wafer test an IC or functionally test I/O connections and power connections in a core region of an IC assembly, while ESD protecting I/O circuits and circuit elements more susceptible to damage from ESD events. Other embodiments, features and advantages will be or will become apparent to those skilled in the art upon examination of the following figures and detailed description. All such additional embodiments, features and advantages are within the scope of the assemblies and methods for the manufacture thereof as defined in the accompanying claims.

### BRIEF DESCRIPTION OF THE FIGURES

The IC, IC assembly and methods for protecting I/O circuits on such devices from ESD can be better understood with reference to the following figures. The components within the figures are not necessarily to scale, emphasis instead being placed upon clearly illustrating the principles of electrically coupling I/O circuits to a protective device. Moreover, in the figures, like reference numerals designate corresponding parts throughout the different views.

FIG. 1 includes a top plan view of an embodiment of a semiconductor die.

FIG. 2 includes a top plan view of an alternative embodiment of a semiconductor die.

FIGS. 3A-3F schematically illustrate a method of constructing the semiconductor die of FIG. 1.

FIGS. 4A-4B include partial side views of an embodiment of an IC assembly.

FIG. 5 is a flow chart illustrating an embodiment of a method for protecting I/O circuits on an IC from ESD.

FIG. 6 is a flow chart illustrating an alternative embodiment of a method for protecting I/O circuits on an IC from ESD.

### DETAILED DESCRIPTION

The invention provides means for dense arrays of high-speed chip-to-chip bonded interconnections to be protected from ESD during handling and assembly (bonding) without area or performance penalty due to ESD protection. This result is achieved by electrically connecting a large number of chip-to-chip bonding terminals to a single remote on-chip ESD protection device before and during chip-to-chip bonding, and then physically severing the connection between the terminals and the ESD device after bonding is completed. The shorting together of the many high-speed interface terminals with the ESD device is accomplished through a thin film metal layer exposed on the chip surface, so that the shorting film is accessible for removal after chip-to-chip bonding.

The shorting layer might be efficiently implemented as a seed layer which is commonly used to initiate plating of the metal (typically copper) forming the bonding terminals. The shorting layer would be patterned to short together sets of high speed input/output terminals to their associated ESD protection devices, while leaving the power supply terminals and low-speed control and test port terminals available for test prior to assembly. (Power supply and other terminals not connected by the shorting layer could be conventionally ESD protected.)

The shorting layer can be physically removed by etching after the chip-to-chip bonding is completed. Such etching could be aqueous (e.g., hydrogen peroxide for removal of a tungsten shorting layer), or it could be performed by dry etching (e.g., xenon-difluoride etching of a conductive amorphous silicon layer). Additional testing of the coupled semiconductor dice may be performed after bonding and before removal of the shorting layer. Alternatively, additional testing of the coupled semiconductor dice can be performed after removal of the shorting layer.

An electrically conductive shorting layer is applied over a select region of a semiconductor die to couple relatively high-speed I/O connections to an ESD protection device. An IC arranged with such a conductive shorting layer enables wafer level testing of connections that are electrically isolated from an electrical ground or ESD protective device, while protecting other, I/O circuits from potential damage due to ESD events. Wafer level tested connections may include serial signal ports and power connections. The die can be electrically and physically coupled to a second semiconductor die (or to multiple die) to form an IC assembly. When the high-speed I/O connections are formed by metallic studs extended by metal layers and/or conductive spacers, the IC assembly can be fusion bonded along opposed surfaces of the metal layers.

Multiple ESD protection devices, in contact with the shorting layer, can be arranged near opposed corners of a semiconductor die. Alternatively, ESD protection devices can be arranged along or near opposed sides of the semiconductor die.

Location of the shorting layer along the perimeter of the IC assembly improves access to the shorting layer of the respective semiconductor dice for post-bond removal. While a perimeter arrangement of the high-speed connections may be desired for fusion bonded IC assemblies consisting of two similarly sized semiconductor dice, a perimeter arrangement of the high-speed connections is natural for fusion bonded IC assemblies consisting of a primary die with one or more smaller overlapping bridge dice connecting a neighboring primary die. However, it should be understood that high-speed connections protected by the shorting layer need not be exclusively located at or proximal to the die perimeter.

The shorting layer or shorting layers can be removed via exposure to a liquid or gas in an etching process. Upon completion of wafer testing of connections electrically isolated from the conductive shorting layer followed by die bonding, the electrically conductive shorting layer or shorting layers (from the respective dice) are removed to electrically isolate and thereby enable the relatively high-speed I/O connections between the first semiconductor die and the second semiconductor die.

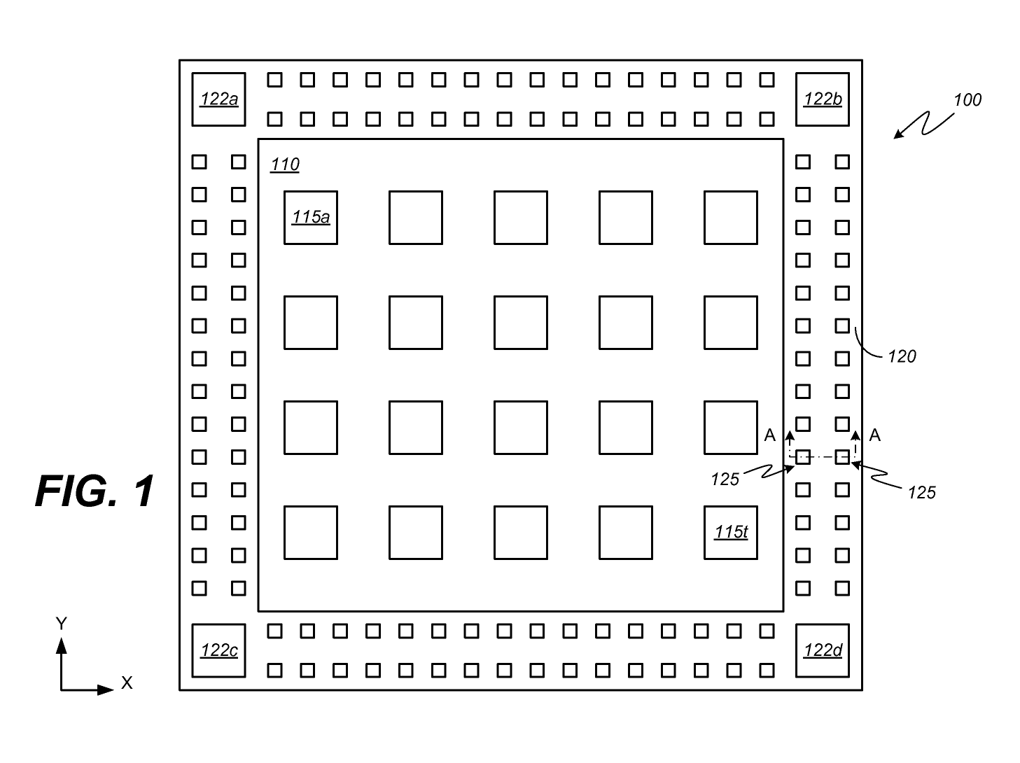

Turning now to the drawings, wherein like reference numerals designate corresponding parts throughout the drawings, reference is made to FIG. 1, which includes a top plan view of an embodiment of a semiconductor die 100. The semiconductor die 100 includes a core region 110 and a second or select region 120 (i.e., a non-core region) that are arranged along an active surface of the semiconductor die 100. The core region 110 includes respective circuits or circuit elements that support low-speed I/O ports or provide power to the integrated circuits on the semiconductor die 100. In the example embodiment, the core region 110 includes twenty sub-regions. In other embodiments, the core region 110 may include less or more sub-regions as may be desired. Each of the sub-regions has at least one pad or electrically conductive element arranged along the uppermost surface of the semiconductor die 100. In the example embodiment, the core region 110 includes sub-region 115a, which includes circuit elements that support a serial I/O port, and sub-region 115t, which includes circuit elements that buffer a direct-coupled (DC) voltage. In the example embodiment, the core region 110 is substantially square-shaped. It should be understood that the core region 110 is not so limited and can be arranged in other non-square shapes.

The second or select region 120 includes at least one ESD protective device 122 and metallic studs 125. The ESD protective device 122 is electrically coupled to each of the metallic studs 125 by an electrically conductive shorting layer. The shorting layer is formed from tungsten, titanium, or a compound of tungsten and titanium deposited or otherwise applied along the active surface of the semiconductor die 100 above the select region 120. In an alternative embodiment, the shorting layer may be formed of a conductive polysilicon. The conductive polysilicon can be controllably removed by a gaseous etching agent (e.g., a gas including a compound of xenon diflouride). The core region 110 is masked or otherwise protected while the shorting layer is formed on the semiconductor die 100, or the shorting layer could be deposited across the entire die and removed from the core region 110 while protected in the select region 120.

In the example embodiment, the select region 120 entirely surrounds the core region 110. The select region 120 is not limited to the illustrated arrangement. For example, the select region 120 may be arranged along one or more edges of the semiconductor die 100. When the select region 120 is arranged along two edges of the semiconductor die 100, the select region 120 may include adjacent edges or opposed edges of the semiconductor die 100. However arranged, the select region 120 is wide enough to electrically couple the ESD protective device 122 to each of the metallic studs 125. In the example embodiment, the select region 120 is substantially wider than the ESD protective device 122 and the metallic studs 125. However, the select region 120 is not so limited and can be arranged in other widths or shapes that do not entirely encompass but still contact at least some portion of an ESD protective device 122 and the metallic studs 125.

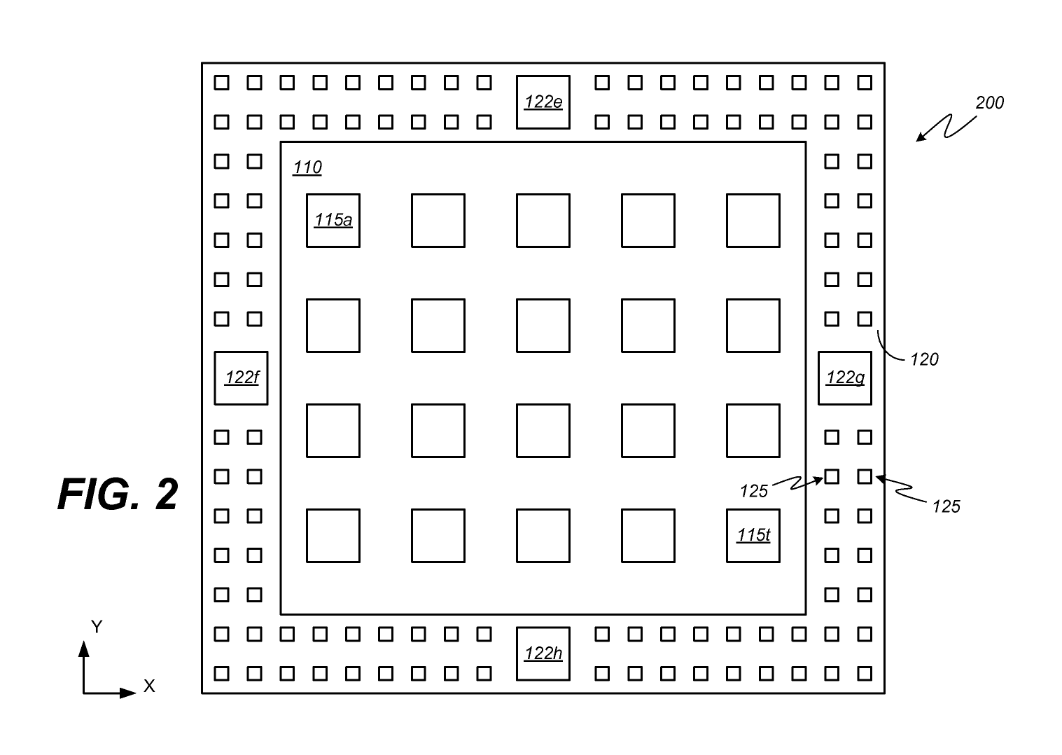

An ESD protective device 122 is any circuit or arrangement of circuits and circuit elements intended to divert potentially damaging electrostatic charge transfers away from sensitive circuitry, such as circuitry coupled to respective metallic studs 125. In the example embodiment, the semiconductor die 100 is arranged with ESD protective devices 122a-122d near each corner of the die. A first ESD protective device 122a is located near a first corner. A second ESD protective device 122d is located near a second corner opposed to the first corner and the first ESD protective device 122a. A third ESD protective device 122b and fourth ESD protective device 122c are located near respective corners of the semiconductor die 100. As shown in FIG. 2, ESD protective devices 122e-122h can be located proximal to the center of each edge of the semiconductor die 100 rather than near each corner of the semiconductor die 100. In an alternative embodiment (not shown), ESD protective devices 122 can be distributed throughout the select region 120 as may be desired. For example, the arrangements illustrated in FIG. 1 and FIG. 2 can be combined when the desired number of I/O connections supported by the metallic studs 125 and the area of the semiconductor die 100 permits.

The metallic studs 125 extend above the upper surface of the semiconductor die 100 along an axis orthogonal to both the Y-axis and the X-axis. The metallic studs 125 are coupled to one or more ICs or circuit elements that support relatively high-speed I/O connections when the semiconductor die 100 is arranged in a die-to-die IC assembly with a second similarly configured semiconductor die. For illustrative purposes, only a single semiconductor die is presented in FIG. 1 and in FIG. 2. In these example embodiments, the metallic studs 125 are arranged in two rows along each edge of the semiconductor die 100. In alternative embodiments, the metallic studs 125 can be arranged in different and regular patterns or even in irregular patterns as may be desired. Note that the example embodiments illustrated in FIG. 1 and FIG. 2 that show a high-speed shorted region around the entire perimeter of a semiconductor die is typical of a multi-chip assembly with a central chip connected by bridge chips to neighbors on all four sides. In a more general case (not shown), the core or unshorted region(s) 110 and the select or shorted region(s) 120 could be interspersed as may be desired.

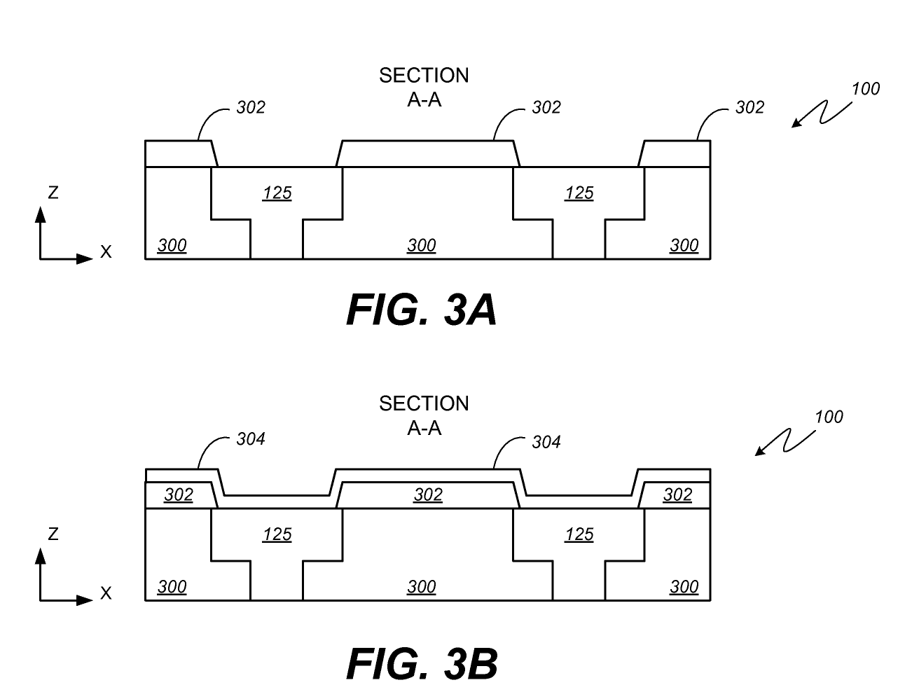

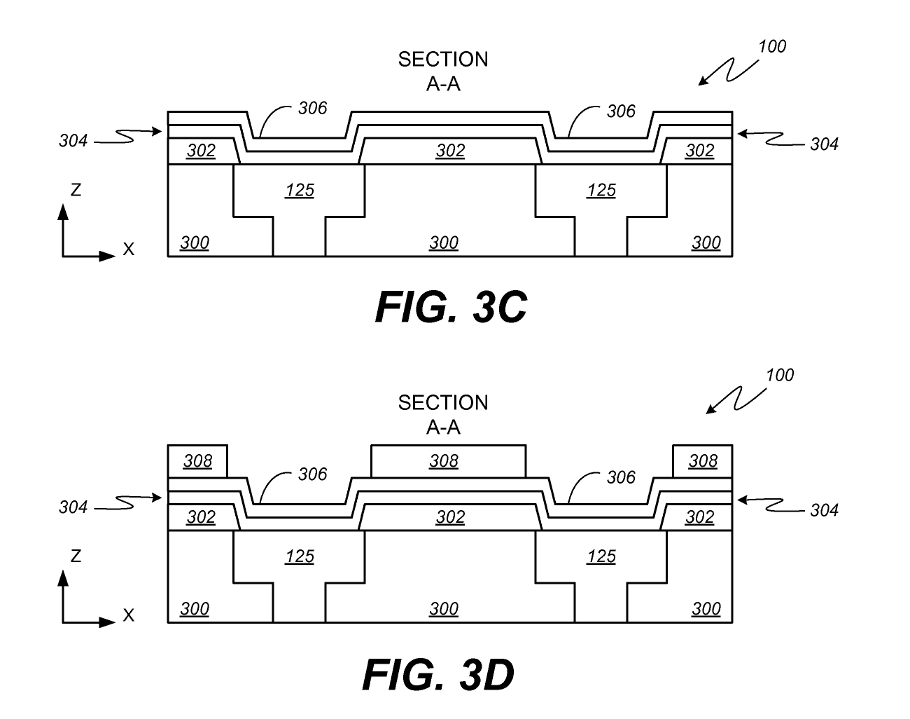

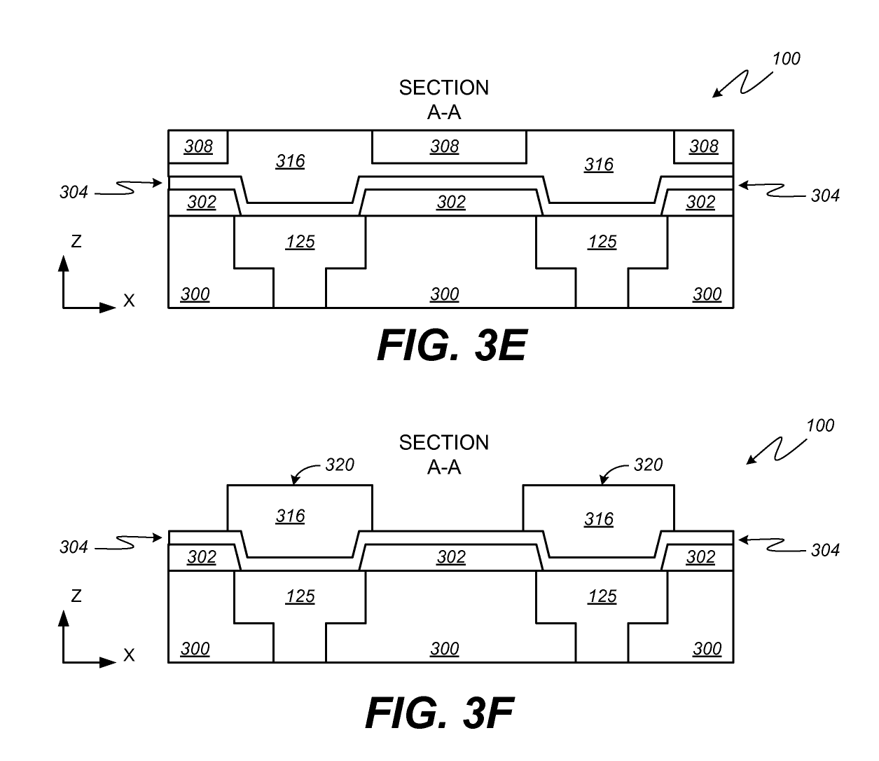

FIGS. 3A-3F schematically illustrate a method of constructing the metallic studs 125 of the semiconductor die 100 of FIG. 1 by way of section A-A. FIGS. 3A-3F show a preferred embodiment where the shorting layer is implemented as the seed layer (or part of the seed layer) in an electroplating process for formation of the studs 125. Although illustrated in a cross-sectional view in the direction of line A-A (FIG. 1), the schematic illustrations in FIGS. 3A-3F are depicted without cross-hatching. Similar layers or structures comprising the same material or compound in FIGS. 3A-3F are indicated by a shared reference numeral. For example, FIG. 3A indicates that the metallic studs 125 begin as a top metal structure in an insulating layer 300. Layer 300 and metallic studs 125 represent only the topmost elements of the interconnect stack of the die, with multiple layers (not shown) below layer 300 and metallic studs 125, extending from a substrate (not shown) to a surface of the semiconductor die 100. An optional dielectric layer 302 is deposited and patterned to expose a surface of the metallic studs 125. FIG. 3B shows that a conformal shorting layer 304 of tungsten, titanium or a compound of titanium tungsten (or other appropriate metals) is deposited or otherwise applied above the dielectric layer 302 and the metallic studs 125. Alternatively, the shorting layer 304 may comprise a polysilicon or amorphous silicon material doped with conductive elements. Thereafter, as shown in FIG. 3C, an optional metal layer 306 is electroplated above the shorting layer 304 to reduce shorting layer electrical resistance. Next, as shown in FIG. 3D, a second temporary dielectric layer 308 (typically photoresist) is deposited and patterned to expose the optional metal layer 306 or the shorting layer 304 above the metallic studs 125. In FIG. 3E, copper or other metals are introduced by way of an electroplating process on the semiconductor die 100 to form metal layer 316. Metal layer 316 increases the length of the metallic studs 125 in the Z dimension. Once the metal layer 316 has attained a desired height in the Z dimension, the electroplating process is terminated and as shown in FIG. 3F the temporary dielectric layer 308 and the optional metal layer 306 are removed leaving the shorting layer 304 and the upper surfaces including respective contact surfaces 320 of the metal layer 316 exposed.

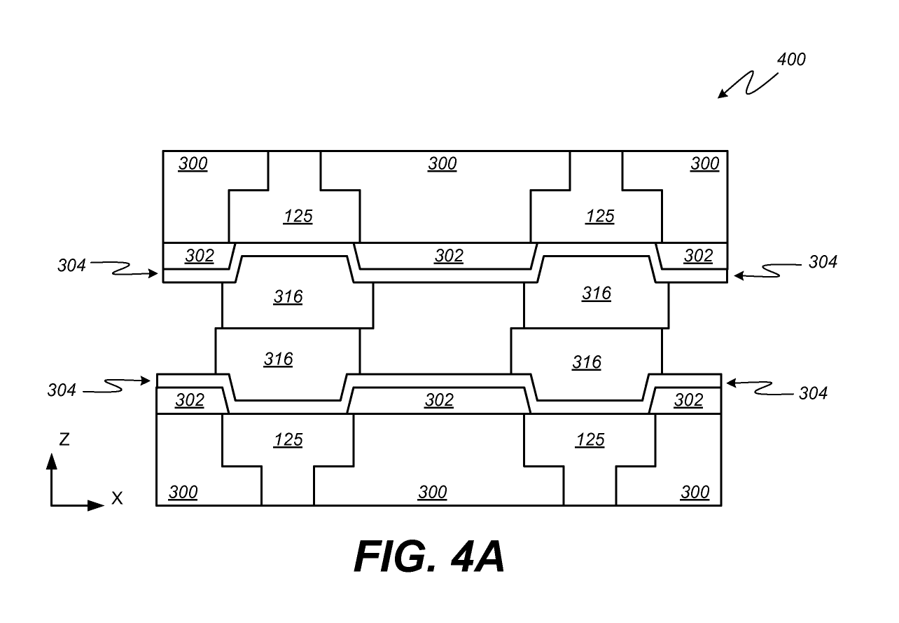

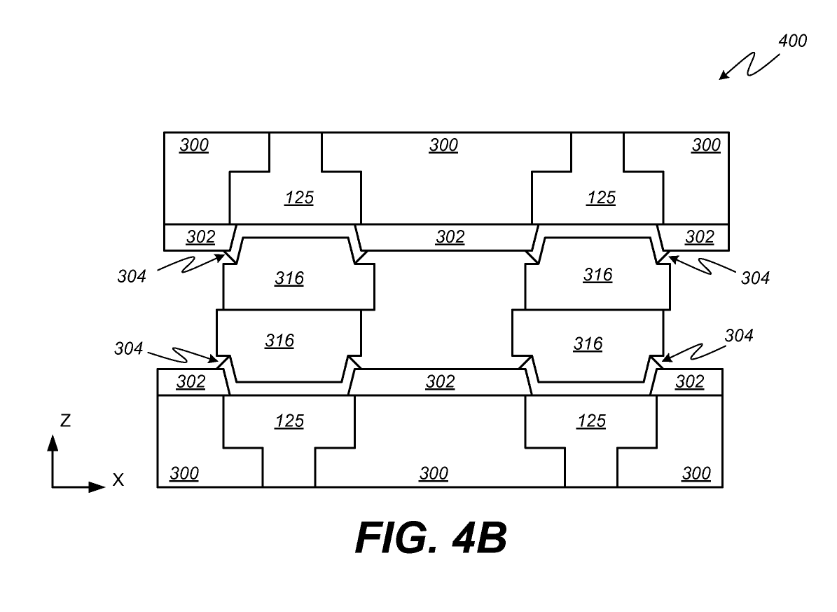

FIGS. 4A-4B include partial side views of an embodiment of an IC assembly 400. The IC assembly 400, as illustrated in FIG. 4A, comprises first and second instances of the semiconductor die 100 in close registration (i.e., substantially aligned with each other in the X and Y dimensions) with the respective contact surfaces 320 fusion bonded to one another to complete a physical die-to-die connection between the first and second instances of the semiconductor die 100. The shorting layer 304 shorts the metallic studs 125 and circuits coupled to the metallic studs 125 to the ESD protective devices 122. Thus, the relatively higher-speed I/O connections are still inoperable at this stage.

In an alternative arrangement, the respective contact surfaces 320 may be physically and electrically coupled to each other with solder (not shown). In still another alternative arrangement, additional conductive spacers (not shown) can be added to one or both of the contact surfaces 320 of the respective semiconductor die 100 to provide access to the power and serial test connections located within the core region 110 of the assembly 400. The additional conductive spacers can be fusion bonded and/or soldered to the respective metal layers 316 on the semiconductor dice 100. The conductive spacers used to connect terminals in the core region 110 of one die to another might consist of plated pillars such as those described for the connections in the select region 120, which might be formed during the same process steps described in FIGS. 3A-3F. If the same pillar formation process is shared by both the select region(s) 120 and the core region(s) 110, then an additional masking step is used to remove the shorting layer 304 from the core region(s) 110 while retaining it in the select region(s) 120.

ESD protection is provided by the electrical coupling of the shorting layer 304 to the one or more ESD protective devices 122 (FIG. 1 and FIG. 2) during the construction of the separate semiconductor dice 100, wafer level testing of circuits in the core region 110, shipping, alignment, and fusion bonding or soldering. Power and serial test connections arranged in the core regions 110 of the IC assembly 400 are protected by conventional ESD methods. As indicated in FIG. 4B, the relatively higher-speed I/O connections supported by the metallic studs 125 and metal layers 316 are enabled by electrically isolating the respective connections from each other and the one or more ESD protective devices 122 by removing the shorting layer 304 between the connections. The shorting layer 304 can be removed by exposure to wet or gaseous etching agents for a required time. An example gas suitable for etching a shorting layer of conductive polysilicon or amorphous silicon includes a compound of xenon difluoride. Example wet etching agents for removal of a layer of tungsten or a layer of tungsten titanium include hydrogen peroxide or hydrofluoric acids diluted in water.

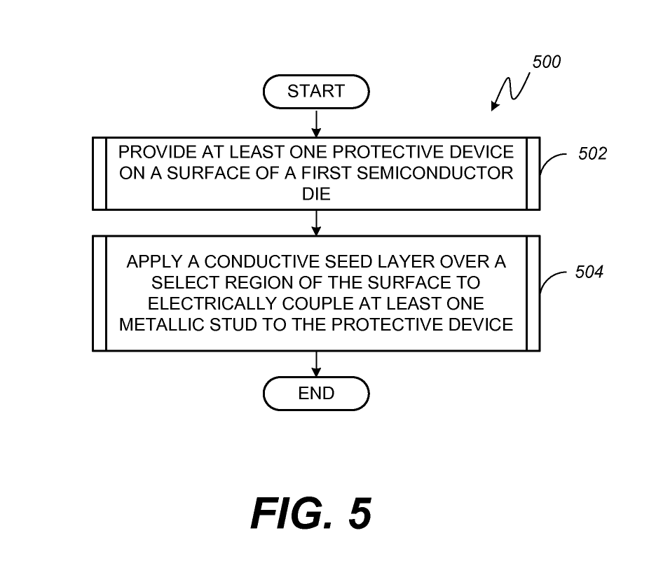

FIG. 5 is a flow chart illustrating an embodiment of a method 500 for protecting I/O circuits on an IC from ESD. The method 500 begins with block 502 where at least one protective device (e.g., an ESD protective device 122) is provided along a surface of a first semiconductor die 100. In block 504, a conductive shorting layer 304 is applied over a select region 120 of the surface of the first semiconductor die 100 to electrically couple at least one metallic stud 125 to the at least one protective device 122. The metallic stud 125 is further coupled to circuits or circuit elements that support a relatively high-speed die-to-die I/O connection when the first semiconductor die 100 is placed in registration with and bonded or soldered to at least one other suitably configured semiconductor die.

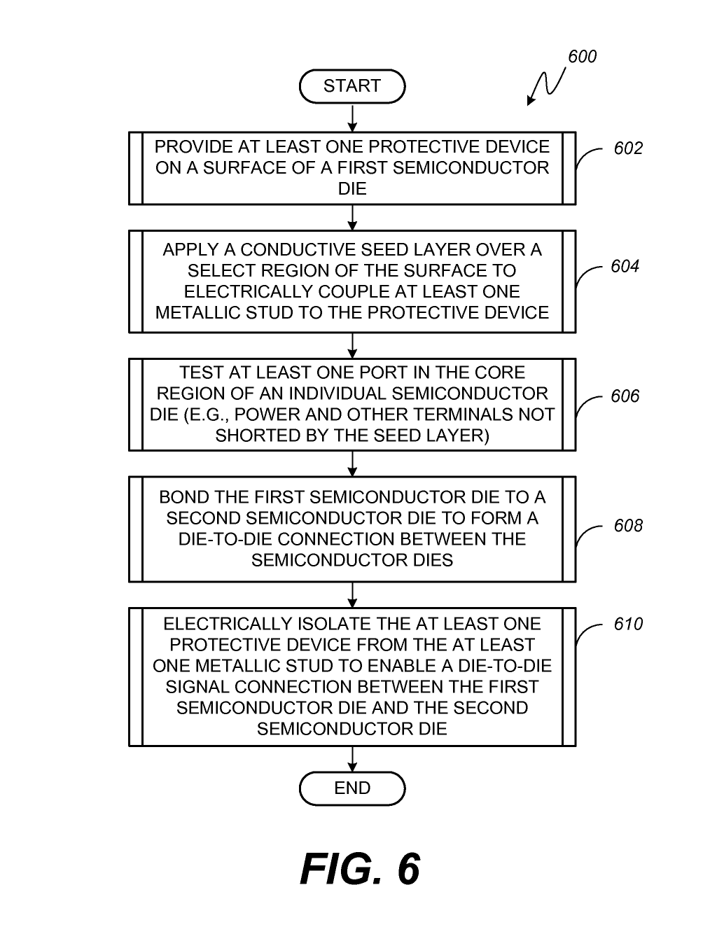

FIG. 6 is a flow chart illustrating an alternative embodiment of a method 600 for protecting I/O circuits on an IC from ESD. The method 600 begins with block 602 where at least one protective device (e.g., an ESD protective device 122) is provided along a surface of a first semiconductor die 100. In block 604, a conductive shorting layer 304 is applied over a select region 120 of the surface of the first semiconductor die 100 to electrically couple at least one metallic stud 125 to the at least one protective device 122. In block 606, at least one port in the core region (i.e., a terminal) of an individual semiconductor die is tested. As further indicated in block 606, the tested port is a power or signal terminal that is not shorted by the shorting layer 304 or otherwise coupled to the ESD protective device 122. In block 608, the first semiconductor die is bonded or soldered to a second semiconductor die to form a die-to-die connection between the respective semiconductor dice. Thereafter, in block 610, the at least one protective device 122 is electrically isolated from the at least one metallic stud 125 to enable a die-to-die signal connection between the first semiconductor die and the second semiconductor die. Note that additional testing of one or both of the integrated circuits of the bonded assembly can occur both prior to and after removal of the shorting layer 304. As indicated above, the metallic stud 125 is further coupled to circuits or circuit elements that support a relatively high-speed die-to-die I/O connection. Thus, the combination of bonding or soldering the first and second semiconductor dice together and removing the shorting layer to electrically isolate the coupled metallic studs 125 of the respective semiconductor dice from the at least one protective device 122 enables a die-to-die signal connection between the respective semiconductor dice.

While various example embodiments of ICs, IC assemblies and methods for protecting I/O circuits on an IC from ESD have been described, it will be apparent to those skilled in the art that many more embodiments and implementations are possible that are within the scope of this disclosure. Accordingly, the described IC assemblies and methods for protecting circuits therein from ESD events are not to be restricted or otherwise limited except in light of the attached claims and their equivalents.

What is claimed is:

1. A method for protecting input/output circuits on an integrated circuit from electrostatic discharge, the method comprising:
providing at least one protective device on a surface of a first semiconductor die; and
applying a conductive shorting layer over a select region of the surface to electrically couple at least one metallic stud to the at least one protective device.

2. The method of claim 1, wherein the step of providing at least one protective device includes locating the protective device proximal to a perimeter of the first semiconductor die.

3. The method of claim 2, wherein locating the protective device proximal to a perimeter of the first semiconductor die further includes locating a second protective device opposed to the at least one protective device.

4. The method of claim 3, wherein locating the second protective device opposed to the at least one protective device further includes locating the at least one protective device and the second protective device proximal to opposed corners of the first semiconductor die.

5. The method of claim 3, wherein locating the second protective device opposed to the at least one protective device further includes locating the at least one protective device and the second protective device proximal to an edge of opposed sides of the first semiconductor die.

6. The method of claim 1, further comprising:
masking a core region of the surface.

7. The method of claim 6, wherein the core region includes a serial port.

8. The method of claim 6, wherein the core region includes a power port.

9. The method of claim 1, further comprising:
coupling the first semiconductor die to a second semiconductor die such that a die-to-die connection between the first semiconductor die and the second semiconductor die is completed.

10. The method of claim 9, further comprising:
removing the shorting layer to enable a die-to-die signal connection.

11. The method of claim 1, wherein the step of applying a conductive shorting layer over a select region of the surface includes applying a conformal layer of tungsten.

12. The method of claim 1, wherein the step of applying a conductive shorting layer over a select region of the surface includes applying a conformal layer of a compound of tungsten and titanium.

13. The method of claim 1, further comprising:
electroplating a first metal layer adjacent to the shorting layer to reduce shorting layer electrical resistance.

14. The method of claim 13, further comprising:
applying a dielectric layer over select regions of the first metal layer.

15. The method of claim 14, further comprising:
forming a second metal layer in registration with the at least one metallic stud.

16. The method of claim 15, further comprising:
exposing the shorting layer.

17. The method of claim 16, further comprising:
testing a port in the core region;
aligning and coupling a second semiconductor die to the first semiconductor die to create an integrated circuit assembly; and
electrically isolating the at least one protective device from the at least one metallic stud.

18. The method of claim 17, wherein the step of aligning and coupling comprises fusion bonding and the step of electrically isolating the at least one protective device from the at least one metallic stud comprises introducing a liquid compound that etches the shorting layer.

19. The method of claim 17, wherein the step of aligning and coupling comprises fusion bonding and the step of electrically isolating the at least one protective device from the at least one metallic stud comprises introducing a gas that etches the seed layer.

20. The method of claim 19, wherein the gas comprises xenon difluoride.

21. An integrated circuit (IC) assembly, comprising:
a first semiconductor die having a first surface and an opposed surface, the first semiconductor die further having at least one protective device arranged on the first surface, the at least one protective device located within a conductive shorting layer in a select region of the first semiconductor die, the conductive shorting layer electrically coupling at least one conductive element to the at least one protective device; and
a second semiconductor die including at least one respective conductive element that when arranged in registration and coupled with the first semiconductor die completes a circuit between the first semiconductor die and the second semiconductor die.
